(19) United States
(12) Patent Application Publication
(10) Pub. No.: US 2002/0093101 A1
(43) Pub. Date: Jul. 18, 2002

(54) Method of metallization using a nickel-vanadium layer

(76) Inventors: Subramoney Iyer, (US); Murali Narasimhan, San Jose, CA (US); Murali Abburi, Santa Clara, CA (US); Vijayashree Subramanyam, Santa Clara, CA (US)

Correspondence Address: Patent Counsel, Applied Materials, Inc., 3050 Bowers Avenue, P.O. Box 450A, Santa Clara, CA, 95052, US

(21) Appl. No.: 09/881,450

(22) Filed: Jun. 13, 2001

Related U.S. Application Data
(60) Provisional application No. 60/213,130, filed on Jun. 22, 2000.

(51) Int. Cl. H01L 23/52; H01L 23/48; H01L 29/40

(52) U.S. Cl. 257/758

(57) ABSTRACT

A method of metallization comprising forming a conductive layer comprising nickel and vanadium inside an opening. The conductive layer comprising nickel and vanadium can be used as a barrier layer to prevent interlayer metal diffusion. Alternatively, the conductive layer can also be used as a seed layer for subsequent metal electroplating. In one embodiment, the conductive layer is used as an integrated barrier and seed layer for subsequent copper plating for submicron applications.

### CROSS REFERENCE TO RELATED APPLICATIONS

This application claims priority to U.S. provisional application 60/213,130, entitled “A Method of Metallization Using a Nickel-Vanadium Layer”, filed on Jun. 22, 2000, which is incorporated here in by reference in its entirety.

### BACKGROUND OF THE DISCLOSURE

1. Field of the Invention

The invention relates to a method of forming a copper metallization structure.

2. Background of the Invention

Copper and its alloys are increasingly being used for metal interconnects in advanced integrated circuit fabrication because they have lower resistivities and better electromigration performance compared to aluminum. Copper can be deposited on high aspect ratio via and contact structures using chemical vapor deposition (CVD), physical vapor deposition (PVD) or metal electroplating.

A typical electroplating sequence generally comprises vapor depositing a barrier/liner layer over the via or contact, vapor depositing a conductive metal seed layer over the barrier/liner layer, and then electroplating a conductive metal (e.g., copper) over the seed layer to fill the via or contact structure.

The barrier/liner layer, which prevents undesirable interlayer diffusion and promotes adhesion between a subsequently deposited metal layer and the underlying substrate, typically comprises a refractory metal and a refractory metal nitride, e.g., tantalum and tantalum nitride. Alternatively, the refractory metal or nitride layers may also be used separately as a barrier or liner layer. A relatively thin copper layer, which may be deposited by CVD or PVD, is often used as a seed layer to promote subsequent metal electroplating. However, depositing two layers (barrier/seed) is relatively expensive, and there is a need for a method of metallization with reduced cost and process complexity.

### SUMMARY OF THE INVENTION

The present invention provides a method of metallization comprising forming a conductive layer comprising nickel and vanadium inside an opening, prior to forming a metal layer. According to one aspect of the invention, the opening may be a contact, via or trench, and the conductive layer comprising nickel and vanadium is formed by physical vapor deposition. The metal layer may, for example, be a copper layer formed by chemical vapor deposition or electroplating. In one embodiment, the conductive layer comprising nickel and vanadium has a thickness of at least about 200 Å, and in another embodiment, at least about 1000 Å.

### BRIEF DESCRIPTION OF THE DRAWINGS

The teachings of the present invention can be readily understood by considering the following detailed description in conjunction with the accompanying drawings, in which:

FIG. 1 is a schematic representation of an apparatus suitable for practicing the present invention;

FIG. 2 is a physical vapor deposition chamber suitable for practicing the present invention;

FIG. 3 is a process sequence for practicing the invention;

FIGS. 4a-d are schematic cross-sectional views of a substrate during metallization processing according to one embodiment of the invention; and

FIGS. 5a-d are schematic cross-sectional views of a substrate during metallization processing according to another embodiment of the invention.

To facilitate understanding, identical reference numerals have been used, where possible, to designate identical elements that are common to the figures.

### DETAILED DESCRIPTION

The present invention provides a method of forming a metallization structure incorporating a conductive layer comprising nickel (Ni) and vanadium (V)—e.g., a Ni—V layer. In one embodiment, the conductive Ni—V layer is formed inside an opening that extends to an underlying conductive or semiconducting layer or substrate. The opening is generally a contact, via or trench. The Ni—V layer acts as a barrier layer to minimize interlayer diffusion between a subsequently deposited metal layer and the underlying layer or substrate. Furthermore, the Ni—V layer may serve as a seed layer for subsequent metal deposition—e.g., electroplating or chemical vapor deposition (CVD). According to embodiments of the invention, the Ni—V layer may be formed by physical vapor deposition (PVD).

By using the Ni—V layer as an integrated barrier and seed layer, conformal step coverage to high aspect ratio openings can be achieved, with advantages such as reduced manufacturing cost and increased process throughput.

Apparatus

The process of the present invention can be performed in either a multi-chamber or integrated processing system (e.g., a cluster tool) having both PVD and CVD chambers, or separate single-chamber systems. The use of an integrated processing system is preferred because the substrate can be kept within a vacuum environment to prevent contamination between processing steps. Examples of integrated processing systems include PRECISION 5000®, ENDURA® and CENTURA® platforms used in conjunction with processing chambers such as a VECTRA IMP™, Coherent and Standard PVD chamber, or a TxZ™ CVD chamber, among others. These integrated processing systems and chambers are commercially available from Applied Materials, Inc., Santa Clara, Calif.

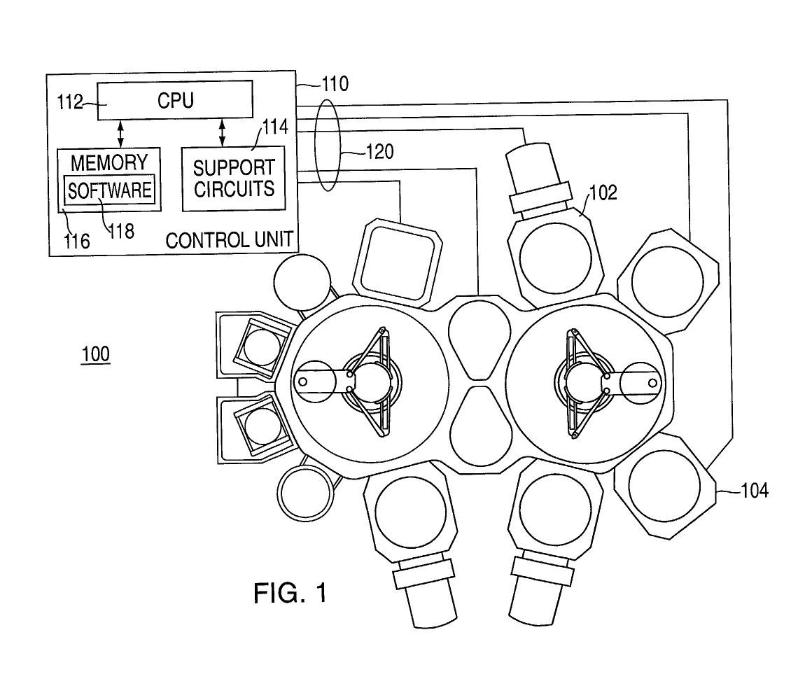

FIG. 1 depicts a schematic representation of an integrated processing system 100, e.g., an ENDURA system, suitable for practicing embodiments of the present invention. A similar staged-vacuum wafer processing system is disclosed in U.S. Pat. No. 5,186,718, entitled “Staged-Vacuum Wafer Processing System and Method,” issued to Tepman et al. on Feb. 16, 1993, which is incorporated herein by reference. The particular embodiment of the system 100 shown herein is suitable for processing planar substrates, such as semiconductor substrates, and is provided to illustrate the invention, and should not be used to limit the scope of the invention. The system 100 typically comprises a cluster of interconnected process chambers, for example, a CVD chamber 102 and a PVD chamber 104.

The processes of the present invention can be implemented using a computer program product or microprocessor controller that executes on a conventional computer system. As illustrated in FIG. 1, a control unit 110 comprises a central processor unit (CPU) 112, support circuitry 114, and memories 116 containing associated control software 118. The control unit 112 is used for automated control of the numerous steps required for wafer processing —such as wafer transport, gas flow control, temperature control, chamber evacuation, and so on. Bi-directional communications between the control unit 112 and various components of the integrated processing system 100 are handled through numerous signal cables collectively referred to as signal buses 120, some of which are illustrated in FIG. 1.

PVD Chamber

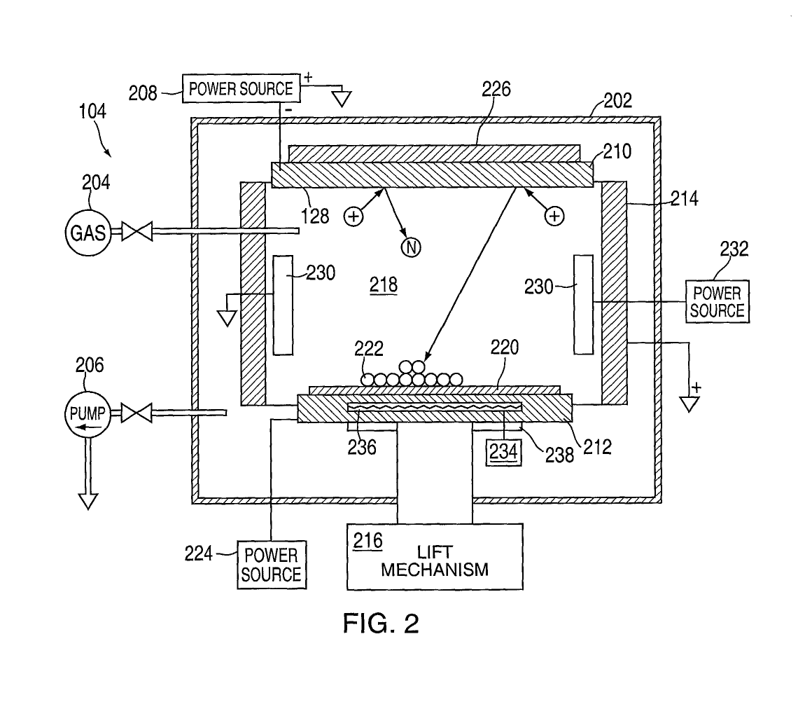

FIG. 2 illustrates a cross-sectional view of an example of a PVD chamber 104 that is suitable for practicing the embodiments of the invention. The PVD chamber 104 comprises a vacuum chamber 202, a gas source 204, a pumping system 206 and a target power source 208. Inside the vacuum chamber 202 is a target 210, a vertically movable pedestal 212, and a shield 214 enclosing a reaction zone 218. A lift mechanism 216 is coupled to the pedestal 212 to position the pedestal 212 relative to the target 210.

A substrate 220 is supported within the chamber 202 by the pedestal 212, and is generally disposed at a certain distance from the target 210. The pedestal 212 may be moved along a range of vertical motion within the chamber 202 by the lift mechanism 216. A resistive heater 236 which is connected to a heater power supply 234 is used to maintain the substrate 220 at a desired process temperature. For processes requiring temperatures below room temperature, a chiller 238, which is attached to the pedestal 212, is used for cooling the pedestal 212 to a desired operating temperature.

Although the target 210 may comprise, as a material to be deposited, an insulator or semiconductor, the target 210 generally comprises a metal—e.g., titanium (Ti), tungsten (W), aluminum (Al), copper (Cu), nickel (Ni), among others. Alternatively, the target 210 may also comprise several components for deposition of a multi-component film. The target 210 is coupled to a target power source 208.

The target power source 208 may comprise a DC source, a radio frequency (RF) source or a DC-pulsed source. When power is applied to the target 210, a plasma is formed from the process gas in the reaction zone 218, comprising ions, electrons and neutral atoms. If the target power source 208 is DC or DC-pulsed, then the target 210 acts as a negatively biased cathode and the shield 214 is a grounded anode. If the target power source 208 is an RF source, then the shield 214 is typically grounded and the voltage at the target 210 varies relative to the shield 214 at a radio frequency, typically 13.56 MHz. In this case, electrons in the plasma accumulate at the target 210 to create a self-bias voltage that negatively biases the target 210.

The electric field accelerates the process gas ions toward the target 210 for sputtering target particles from the target 210. These target particles may also become ionized in the plasma. This configuration enables deposition of sputtered and ionized target particles from the target 210 onto the substrate 220 to form a film 222. The shield 214 confines the sputtered particles and plasma gas in a reaction zone 218 within the chamber 202, and prevents undesirable deposition of target materials beneath the pedestal 212 or behind the target 210.

During sputter deposition, an inert gas, such as argon (Ar), xenon (Xe), neon (Ne), or some other inert gas, is introduced into the vacuum chamber 202. The chamber pressure is controlled by the pumping system 206. For example, a plasma is generated from the inert gas by applying a DC bias of about 100-24,000 W, and more typically about 100-10,000 W, to the sputtering target 210. Target materials are sputtered from the target by the plasma, and deposited on the substrate 220.

The PVD chamber 104 may comprise additional components for improving the sputtering deposition process. For example, a power source 224 may be coupled to the pedestal 212 for biasing the substrate 220, in order to control the deposition of the film 222 on the substrate 220. The power source 224 is typically an AC source having a frequency of, for example, about 400 kHz, or between about 350 to about 450 kHz. When the bias power source 224 is applied, a negative DC offset is created (due to electron accumulation) at the substrate 220 and the pedestal 212. The negative bias at the substrate 220 attracts sputtered target material that becomes ionized. The target material is generally attracted to the substrate 220 in a direction that is substantially orthogonal to the substrate 220. As such, the bias power source 224 improves the step coverage of deposited material compared to an unbiased substrate 220.

The PVD chamber 104 may also comprise a magnet 226 or magnetic sub-assembly positioned behind the target 210 for creating a magnetic field proximate to the target 210. In addition, a coil 230 may be proximately disposed within the shield 214, but between the target 210 and the substrate 212. The coil 230 may comprise either a single-turn coil or multi-turn coil that, when energized, ionizes the sputtered particles. The process is known as Ion Metal Plasma (IMP) deposition. The coil 230 is generally connected to an AC source 232 having a frequency of, for example, about 2 MHz. Details of a VECTRA IMP chamber have been disclosed in commonly-assigned U.S. patent application, entitled “IMP Technology with Heavy Gas Sputtering”, Ser. No. 09/430,998, filed on Nov. 1, 1999, which is herein incorporated by reference.

Process

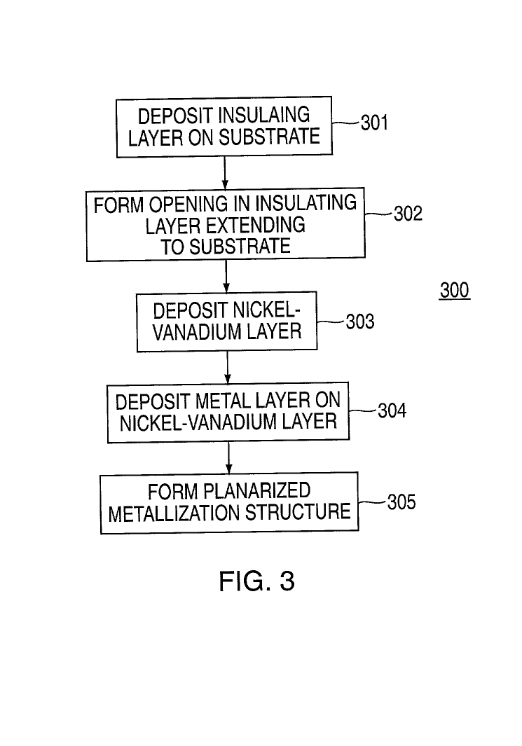

FIG. 3 illustrates a process sequence 300 performed on a substrate according to one embodiment of the invention. In step 301, an insulating layer is deposited on a substrate, e.g., a semiconductor wafer with various material layers formed thereon. The insulating layer may, for example, be an oxide layer. In step 302, the insulating layer is patterned to form at least one opening extending to an underlying layer on the substrate. The underlying layer is a conductive or semiconducting layer, and may be referred to as a “substrate layer”. The opening may generally be a contact, a via or a trench. In this disclosure, the term “contact” refers generally to an opening (formed in a first dielectric layer) that allows contact to be made from a first metal level to a silicon substrate, or to a polysilicon gate or interconnect. The term “via” refers to an opening formed in other intermetal dielectric layers, that allows contact between different metal levels within a multilevel-interconnect structure for the integrated circuit. The term “trench” refers generally to a channel or a line feature.

According to one embodiment of the invention, a conductive layer comprising nickel (Ni) and vanadium (V) (also referred to as a Ni—V layer) is then formed over the insulating layer and inside the opening, as illustrated in step 303. The Ni—V layer can be deposited at relatively high deposition rates using various PVD techniques, e.g., IMP, physical sputtering, among others, using the PVD systems previously described. The Ni—V layer may be formed to different thicknesses, depending on the specific application—e.g., whether the Ni—V layer is to be used as a barrier layer or as a seed layer for subsequent electroplating of copper.

In step 304, a metal layer is formed on the Ni—V layer. In one embodiment, the metal layer is a copper layer formed either by CVD or electroplating using suitable deposition systems such as those described above. If the copper layer is formed by CVD, then a relatively thin Ni—V layer deposited in step 303 (e.g., about 200 Å) will suffice, as long as it is thick enough to be effective as a barrier layer. However, if the copper layer is formed by electroplating, a thicker Ni—V layer (e.g., at least about 1000 Å) is needed to facilitate electroplating.

After metal deposition in step 304, the substrate may be subjected to a planarization step 305 such as chemical mechanical polishing to remove portions of the metal layer and the Ni—V layer outside the opening. This results in a planarized metallization structure comprising the Ni—V and copper layers inside the opening.

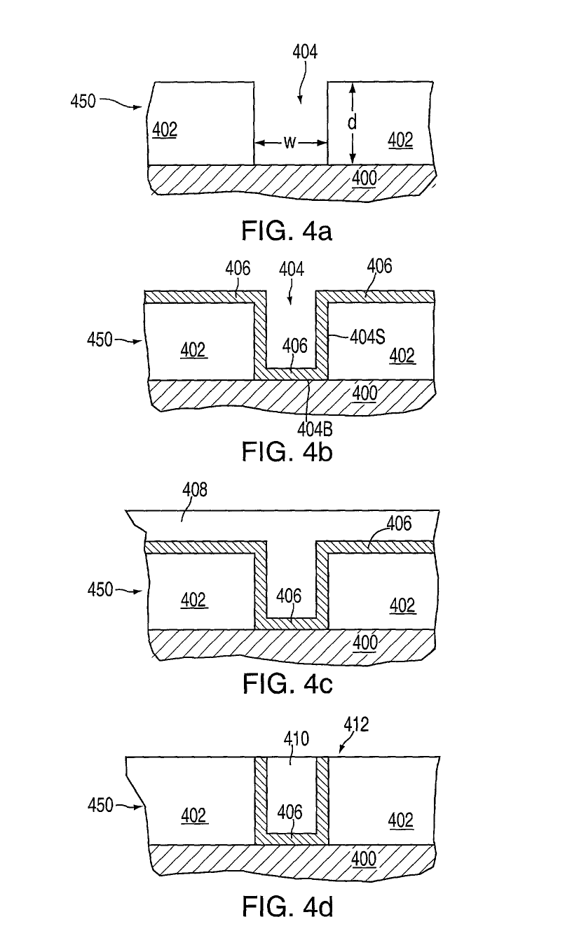

FIGS. 4a-d illustrate cross-sectional views of a substrate structure 450 at various stages of processing that incorporate the present invention. The substrate structure 450 is used generally to denote a substrate such as a semiconductor wafer having one or more material layers formed thereon. FIG. 4a shows an insulating layer 402 that has been patterned to form an opening 404, such as a contact, via, or trench, extending to an underlying material layer or substrate 400. The opening 404 is characterized by an aspect ratio defined by the depth (d) divided by the width (w) of the opening 404. The insulating layer 402 may be a dielectric layer such as a silicon oxide layer, and may comprise dopant species, such as boron and phosphorous, among others. The underlying layer or substrate 400 may comprise semiconducting or conducting materials such as silicon, polysilicon, silicide, aluminum, and tungsten, among others.

According to one embodiment, a Ni—V layer 406 is formed directly on the patterned insulating layer 402 and inside the opening 404, as shown in FIG. 4b. The Ni—V layer 406 can be deposited at relatively high deposition rates using various PVD techniques, e.g., IMP, physical sputtering, among others, using PVD systems previously described. The Ni—V layer 406 of FIG. 4b is shown as being conformally deposited inside the opening 404—i.e., with good coverage on the bottom 404B as well as the sidewall 404S of the opening 404. However, the degree of conformal deposition may vary with the exact deposition technique employed.

Using standard PVD sputtering in the PVD chamber 104 of FIG. 2, for example, the Ni—V layer 406 may be deposited with a target DC bias voltage of between about 500 V and about 600 V. Alternatively, a plasma power of between about 100 W to about 24,000 W may be used. A target comprising Ni and V (or a Ni—V target) is used, along with a sputtering gas of argon (Ar) at a flow rate of between about 50 sccm and about 75 sccm. This flow range is meant to be illustrative only, and should be adjusted as appropriate, depending on the chamber volume, operating pressure, pumping speed, and other operation parameters. Other inert gases such as helium (He), neon (Ne), xenon (Xe), among others, may also be used as the sputtering gas. A pressure of between about 0.25 mtorr and about 5 mtorr is typically used, preferably between about 0.6 mtorr and about 2 mtorr.

The pedestal 212 can be maintained at a temperature range of between about 0° C. and about 500° C., preferably between about 100° C. and about 400° C., and more preferably at about 200° C. The Ni—V film properties can further be controlled by adjusting the pedestal temperature within the operating range. For example, the pedestal temperature may affect the grain morphology, and possibly the resistivity of the deposited Ni—V film. It is believed that by cooling the pedestal to below room temperature, e.g., using a sub-zero biasable electrostatic chuck or a low temperature chiller, a Ni—V film with smaller grains or smoother surface may be achieved. To facilitate the sputtering process, the Ni—V target should preferably comprise at least about 7% by weight of vanadium (which is non-ferromagnetic). It is believed that such a composition is necessary to counteract the ferromagnetic properties of nickel. Standard sputtering tends to result in a less conformal Ni—V layer 406, with relatively little deposition on the sidewall 404S of the opening 404.

In another embodiment, IMP deposition may be used to form the Ni—V layer 406 in the PVD chamber 104 of FIG. 2. For example, an inert gas flow rate of between about 50 sccm and about 75 sccm may be used, at a chamber pressure of between about 20 mtorr and about 40 mtorr. Typically, a DC bias voltage between about 500 V to about 600 V is applied to the target 210. Alternatively, a plasma power of between about 100 W to about 24,000 W may be used. In addition, a RF power of between about 1 kW to about 3 kW, preferably between about 1 kW and about 1.5 kW is applied to the coil 230. The process temperature can be maintained between about 0° C. and about 500° C., preferably between about 0° C. and about 50° C. Unlike standard sputtering, IMP results in a more conformal deposition of the Ni—V layer 406.

With a target comprising at least about 7% vanadium by weight, the deposited Ni—V layer 406 also comprises at least about 7% vanadium. The Ni—V layer 406 is deposited at least to a thickness that is effective as a barrier layer. A thickness between about 200 Å and about 300 Å, for example, is usually sufficient. However, to be an effective seed layer for promoting electroplating, a thicker layer is needed. For example, a Ni—V layer 406 having a thickness between about 1000 Å and about 1500 Å will function effectively as a combined seed and barrier layer. In general, the film properties and step coverage dictate the “field” thickness—i.e., the thickness of the deposited Ni—V layer 406 outside of an opening such as a contact, via or trench. For example, in an opening having a width of about 0.3 μm and a depth of about 1 μm, a coverage of about 40% at the bottom of the opening may be achieved with IMP, compared to about 10% bottom coverage achieved with standard PVD. Thus, with IMP deposition, a thinner Ni—V layer 406 may suffice. While the embodiments of the invention are generally applicable to an opening 404 having different dimensions, they are especially well-suited for submicron applications. For example, conformal deposition of the Ni—V layer 406 may be achieved in an opening having a width of less than about 0.25 μm, or an aspect ratio of at least about 4. Thus, not only is the invention applicable to high aspect ratio trenches, but it is particularly useful for contact or via applications, especially those having feature sizes below about 0.5 μm.

A metal layer 408 is subsequently deposited on the Ni—V layer 406, as shown in FIG. 4c. In one embodiment, the metal layer 310 is a copper layer, and may be formed either by CVD or by electroplating using conventional process conditions and systems that are known in the art. For example, the copper layer 310 may be formed in the CVD chamber 102 of the integrated processing system 100, after the Ni—V layer 406 has been deposited in the PVD chamber 104. Such integrated processing is desirable because it results in increased process throughput while minimizing the possibility of contamination between the Ni—V and copper deposition steps.

In another embodiment, the copper layer 408 may be deposited from an electrolyte solution in an electroplating cell such as that of an ELECTRA™ ECP™ system, which is available from Applied Materials, Inc., using process conditions that are known in the art. In this case, the Ni—V layer 406 acts as an effective seed layer to promote copper electroplating. In conventional copper electroplating, a thin copper layer (analogous to the NiV layer 406) is often used as a seed layer. However, the copper seed layer formed by CVD tends to agglomerate, resulting in a discontinuous copper layer, which may lead to non-uniform electroplating. This problem is avoided in the present invention because the Ni—V layer 406 can readily be deposited as a continuous layer using conventional PVD techniques.

Subsequently, a planarized metallization structure 412 of FIG. 4d may be formed by chemical mechanical polishing to remove portions of the copper layer 408 and the Ni—V layer 406 that lie outside the opening 404. The metallization structure 412 comprises the Ni—V layer 406 and a copper feature 410 formed inside the opening 404, with the Ni—V layer 406 acting as a diffusion barrier between adjacent material layers such as the copper feature 410 and the substrate 400.

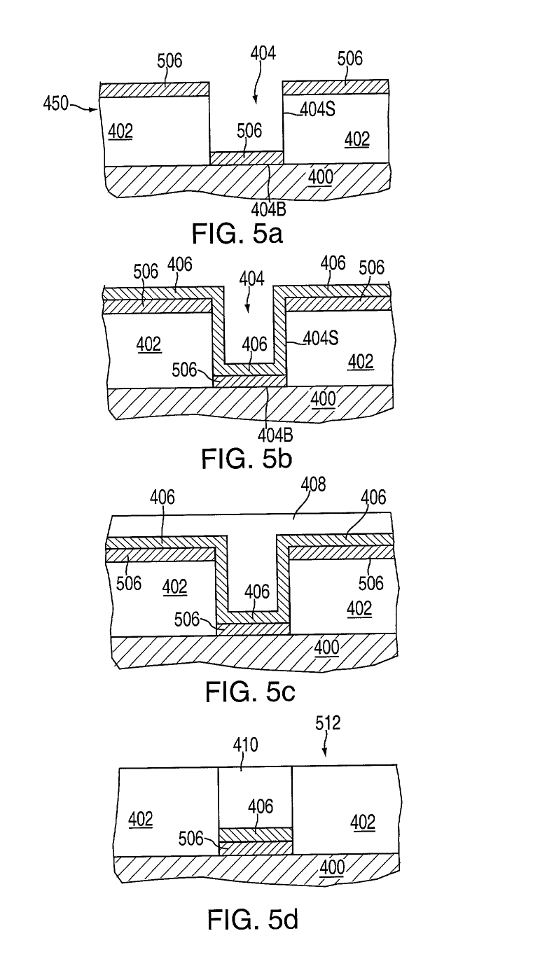

FIGS. 5a-d illustrate an alternative embodiment of the invention, in which a liner layer 506, e.g., a conductive layer such as Ti or Ta, is formed over the patterned insulating layer 402. This liner layer 506 may be formed by conventional chemical vapor deposition (CVD) or PVD techniques. For illustrative purposes, the liner layer 506 is shown in FIG. 5a as a non-conformal layer—i.e., there is relatively little, if any, deposition on the sidewall 404S compared to the bottom 404B of the opening 404. Again, the degree of conformality of the liner layer 506 depends on the specific deposition technique.

For example, the Ti layer 506 may be deposited by thermal CVD using a mixture of titanium tetrachloride (TiCl₄) and hydrogen (H₂), along with inert gases (e.g., argon), if desired. A CVD chamber such as a TxZ™ chamber, available commercially from Applied Materials, Inc., is suitable for this purpose. This CVD Ti deposition may be performed, for example, in the CVD chamber 102 of the integrated processing system 100 such as that illustrated in FIG. 1. In general, the liner layer 506 may also be formed from other refractory metals or their nitrides—e.g., Ta, W, TaN and WN, as long as they are compatible with nickel and vanadium.

As shown in FIG. 5b, the Ni—V layer 406 is then formed on the Ti liner layer 506. One function of the liner layer 506, for example, is to promote adhesion between the underlying material layer or substrate 400 and the subsequently deposited Ni—V layer 406. As previously explained, the Ni-V layer 406 is preferably formed by PVD techniques using, for example, a PVD chamber 104. Thus, the Ti layer 506 and the Ni—V layer 406 can be formed sequentially on a substrate in an integrated processing system 100 illustrated in FIG. 1. The Ni—V layer 406 may be formed to different thicknesses, depending on the specific application for the Ni—V layer 406. Illustratively, to function as an effective barrier layer, the Ni—V layer 406 has a thickness of at least about 200 Å; while a thickness of at least about 1000 Å is preferred if the Ni—V layer 406 is to serve as a seed layer for subsequent metal electroplating. However, the thickness of the layer may vary depending on the application and desired film properties.

After the deposition of the Ni—V layer 406, the metal layer 408 is formed over the Ni—V layer 406 filling the opening 404, as shown in FIG. 5c. In one embodiment, the metal layer 408 is a copper layer deposited by either CVD or electroplating. After the deposition of the metal layer 408, the substrate is subjected to chemical mechanical polishing, or other suitable planarization techniques, to give a planarized metallization structure 512, as shown in FIG. 5d. As illustrated, the metallization structure 512 comprises the liner layer 506, the Ni—V layer 406 and a feature 410 that is formed from the metal layer 408 inside the opening 404.

The metallization structures of the present invention offer several advantages over prior art structures. For example, the integrated Ni—V barrier and seed layer replaces two separate barrier and seed layers (e.g., refractory metal nitride and copper), as required in conventional metallization schemes. Furthermore, the Ni—V layer, which can be formed without any problem of agglomeration, provides an attractive alternative to the conventional copper seed layer. Thus, the invention provides a method with improved reliability, reduced manufacturing cost and increased process throughput. Furthermore, Ni—V has a resistivity that is about 10 to about 20% lower than that of tantalum nitride (TaN), a common barrier layer material. Thus, the use of Ni—V in place of TaN as a barrier layer can result in a metallization structure with reduced contact resistance. In particular, embodiments of the invention are applicable to submicron device fabrication, such as forming a metallization structure in a contact or via having a width of less than about 0.25 μm, or an aspect ratio of at least about 4.

Although several preferred embodiments which incorporate the teachings of the present invention have been shown and described in detail, those skilled in the art can readily devise many other varied embodiments that still incorporate these teachings.

What is claimed is:

1. A method of forming a metallization structure in an integrated circuit, comprising:
forming an insulating layer on a substrate layer;
forming at least one opening in the insulating layer extending to the substrate layer;
forming a conductive layer comprising nickel and vanadium inside the at least one opening; and
forming a metal layer on the conductive layer.

2. The method of claim 1, wherein the at least one opening is a contact or via.

3. The method of claim 1, wherein the at least one opening has an aspect ratio of at least about 4.

4. The method of claim 1, wherein the conductive layer comprising nickel and vanadium is formed by physical vapor deposition.

5. The method of claim 4, wherein the physical vapor deposition is performed with a DC bias voltage between about 500 and about 600 V applied to a physical sputtering target.

6. The method of claim 4, wherein the conductive layer comprising nickel and vanadium has a vanadium weight percent of at least about 7%.

7. The method of claim 5, wherein the physical vapor deposition is performed at a pressure between about 20 and about 40 m torr.

8. The method of claim 5, wherein the physical vapor deposition is performed at a pressure between about 0.25 and about 5 m torr.

9. The method of claim 1, wherein the metal layer comprises copper.

10. The method of claim 9, wherein the conductive layer comprising nickel and vanadium has a thickness of at least about 200 Å.

11. The method of claim 9, wherein the conductive layer comprising nickel and vanadium has a thickness of at least about 1000 Å and the metal layer is formed by electroplating.

12. A method of forming a metallization structure in an integrated circuit, comprising:
forming an insulating layer on a substrate layer;
forming at least one opening in the insulating layer extending to the substrate layer;
forming a first conductive layer inside the at least one opening;
forming a second conductive layer on the first conductive layer inside the at least one opening, wherein the second conductive layer comprises nickel and vanadium; and
forming a metal layer on the second conductive layer.

13. The method of claim 12, wherein the at least one opening is a contact or via.

14. The method of claim 12, wherein the opening has an aspect ratio of at least about 4.

15. The method of claim 12, wherein the first conductive layer comprises a refractory metal.

16. The method of claim 15, wherein the refractory metal is selected from the group consisting of titanium, tantalum, and tungsten.

17. The method of claim 12, wherein the second conductive layer is formed by physical vapor deposition.

18. The method of claim 12, wherein the second conductive layer has a thickness of at least about 200 Å.

19. The method of claim 12, wherein the second conductive layer has a thickness of at least about 1000 Å and the metal layer is formed by electroplating.

20. The method of claim 12, wherein the metal layer comprises copper.

21. The method of claim 17, wherein the second conductive layer has a vanadium weight percent of at least about 7%.

22. The method of claim 17, wherein the physical vapor deposition is performed with a DC bias voltage between about 500 and about 600 V applied to a physical sputtering target.

23. The method of claim 22, wherein the physical vapor deposition is performed at a pressure between about 20 and about 40 m torr.

24. The method of claim 22, wherein the physical vapor deposition is performed at a pressure between about 0.25 and about 5 m torr.

25. The method of claim 22, wherein the physical vapor deposition is performed using an inert sputtering gas having a flow rate of between about 50 to about 75 sccm.

26. The method of claim 25, wherein the inert sputtering gas is selected from the group consisting of argon, helium, neon and xenon.

27. A computer storage medium containing a software routine that, when executed, causes a general purpose computer to control a processing system using a method comprising:
forming an insulating layer on a substrate;
forming at least one opening in the insulating layer extending to the substrate;
forming a conductive layer comprising nickel and vanadium inside the at least one opening; and
forming a metal layer on the conductive layer.

28. The computer storage medium of claim 27, wherein the at least one opening is a contact or via.

29. The computer storage medium of claim 27, wherein the at least one opening formed in the insulating layer has an aspect ratio of at least about 4.

30. The computer storage medium of claim 27, wherein the conductive layer is formed by physical vapor deposition.

31. The computer storage medium of claim 27, wherein the metal layer comprises copper.
